(19) United States
(12) Patent Application Publication
(10) Pub. No.: US 2022/0320178 A1
(43) Pub. Date: Oct. 6, 2022

(54) METHODS OF MANUFACTURING PROGRAMMABLE MEMORY DEVICES

(71) Applicant: Jack Zezhong Peng, San Jose, CA (US)

(72) Inventor: Jack Zezhong Peng, San Jose, CA (US)

(21) Appl. No.: 17/211,829

(22) Filed: Mar. 25, 2021

(51) Int. Cl. H01L 27/22; H01L 27/11514; H01L 43/12; H01L 27/24; H01L 45/00

(52) U.S. Cl. CPC H01L 27/222; H01L 27/11514; H01L 43/12; H01L 27/2481; H01L 45/1683

(57) ABSTRACT

Fabrication method of three-dimensional programmable memory in this invention is related to the memory fabrication technology. The present invention includes the following steps: 1) forming a basic structure; 2) forming an interdigital structure on the basic structure; 3) forming the cylindrical memory unit: according to the preset memory structure, the required intermediate medium layer materials are set layer by layer onto the inner wall of the cylindrical trench hole, and finally the core medium material is filled in the cylindrical trench hole to form the core medium material layer. The beneficial effects of the present invention are that the prepared semiconductor memory has high memory density, low process cost, being easy to fabricate.

### CROSS REFERENCE TO RELATED PATENT APPLICATIONS

This application claims the benefit of PCT Application No. PCT/CN2019/105517, filed Sep. 12, 2019, the contents of which are incorporated by reference.

### FIELD

The present invention relates generally to methods of manufacturing semiconductor memory devices, and more particularly, to methods of manufacturing 3D programmable memory devices.

### BACKGROUND OF THE INVENTION

Various digital memory technologies including erasable programmable read-only memory (EPROM), electrically erasable programmable read-only memory (EEPROM), flash memory, NAND-flash memory, hard disk, compact disk (CD), digital versatile disk (DVD), and Blu-ray Discs registered by the Blu-ray Disc Association, have been widely used for data memory for more than 50 years. However, the lifetime of the memory media is usually less than 5 to 10 years. The anti-fuse memory technology developed for big data memory cannot meet the demand for massive data memory because of its high cost and low memory density.

### BRIEF SUMMARY OF THE INVENTION

The technical problem to be solved by the present invention is to provide a method for preparing a three-dimensional programmable memory with the characteristics of high density and low cost.

The manufacturing method of the three-dimensional programmable memory includes the following steps:

1) Form a basic structure: set a predetermined number of conductive medium layers and insulating medium layers in a way that the conductive medium layer and the insulating medium layer are vertically stacked one onto another to form the base structure body;

2) Form the interdigital structure on the basic structure body: the basic structure body is divided into two interdigitated interdigital structures by setting a segmenting structure that trenches from the top layer to the bottom layer of the basic structure body, and the interdigital structure includes at least two fingers and one commonly connecting strip, each finger strip in the same interdigitated structure is connected with the commonly connecting strip; the segmenting structure includes an array of cylindrical trench holes and an isolation trench filled with insulating material; The area between the fingers is called the inter-finger area, and the cylindrical trench holes in the same inter-finger area are the ones in the same row.

3) Forming the cylindrical memory unit: according to the preset memory structure, the required intermediate medium layer materials are set layer by layer onto the inner wall of the cylindrical trench hole, and finally the core medium material is filled in the cylindrical trench hole to form the core medium material layer.
Further, in the step 3), the preset memory can be: PN junction type semiconductor memory, Schottky diode type memory or retentive medium memory. The retentive medium memory can be a resistance changeable memory, a magnetic phase changeable memory, a phase changeable memory or a ferroelectric memory.
Further, in the step 2), the cylindrical trench holes are separated from each other.
The step 2) includes:
2a. Divide the basic structure into two staggered interdigitated structures by setting an isolation trench from the top layer to the bottom of the basic structure. The interdigitated structure includes at least two fingers and a commonly connecting strip, and each finger in the interdigitated structure is connected to the commonly connecting strip in the same interdigitated structure;
2b. Fill the isolation trench with insulating material;
2c. Drill trench holes at the isolation trench to form cylindrical trench holes penetrating from top layer to the bottom layer of the base structure, and the cylindrical trench hole encroaches the conductive medium layers and the insulating medium layers of the interdigital structure.
Alternatively, the step 2) includes:
An isolation trench hole is set between the center points of two adjacent cylindrical holes in the same row, and encroaches the two adjacent cylindrical trench holes, and the edge of the isolation trench hole is located between the center points of the two adjacent cylindrical holes; Fill the isolation trench hole with insulating material.

In the step 2), in the cylindrical trench hole array, adjacent holes in the same row can encroach upon each other. The “nearest” edge of the encroaching hole is between the center point of the encroaching hole and the center point of the encroached hole. Here the “nearest” edge is the edge closest to the center of the invaded hole.
Further, the sequence of the steps is:
A) Forming a base structure body: a predetermined number of conductive medium layers and insulating medium layers are set in a manner that the conductive medium layer and the insulating medium layer are vertically stacked one onto another to form the base structure body;
B) Forming the interdigital structure on the basic structure:
B1. Divide the basic structure into two staggered interdigitated structures by setting an isolation trench from the top layer to the bottom of the basic structure. The interdigitated structure includes at least two fingers and a commonly connecting strip, and each finger in the interdigitated structure is connected to the commonly connecting strip in the same interdigitated structure;
B2. Fill the isolation trench with insulating material;
B3. Drill an array of trench holes at the isolation trench to form cylindrical trench holes penetrating from top layer to the bottom layer of the base structure, and the area between the fingers is called the inter-finger area, and the cylindrical trench holes in the same inter-finger area are the ones in the same row.
C) Forming a cylindrical memory unit: according to the preset memory structure, the required intermediate medium layer materials are set layer by layer onto the inner wall of the cylindrical trench hole, and finally the core medium material is filled in the cylindrical trench hole to form the core medium material layer.
Alternatively, the sequence of the steps can be:
I) Forming a base structure body: a predetermined number of conductive medium layers and insulating medium layers are set in a manner that the conductive medium layer and the insulating medium layer are vertically stacked one onto another to form the base structure body;
II) Forming the prototype of the interdigital structure and the cylindrical trench unit on the basic structure:
II 1. Drill an array of trench holes at the isolation trench to form cylindrical trench holes penetrating from top layer to the bottom layer of the base structure; the area between two adjacent arrays of cylindrical trench holes is in the finger strip region;
II 2. According to the preset memory structure, the required intermediate medium layer materials are set layer by layer onto the inner wall of the cylindrical trench hole, and finally the core medium material is filled in the cylindrical trench hole to form the core medium material layer;
III) Forming the prototype of the interdigital structure: isolation trench holes are set between two adjacent cylindrical holes in the same row, and isolation trenches are set at the two ends of each array of cylindrical trench holes. The isolation trench holes encroach the core medium material in the cylindrical trench holes. The isolation trenches are alternately set at the two ends of each finger area, to form two staggered interdigitated structures. And the isolation trenches and isolation trench holes are filled with insulating medium.

The insulating medium in the isolation trench and the isolation trench hole can be silicon dioxide or air.

The beneficial effects of the present invention are that the prepared semiconductor memory has high memory density, low process cost, being easy to fabricate.

### BRIEF DESCRIPTION OF THE DRAWINGS

FIG. 1 is a schematic diagram of a three-dimensional structure of a semiconductor memory obtained by the manufacturing method of Embodiment 1 of the present invention.

FIG. 2 is a schematic diagram (from top view direction) of the storage unit of the present invention.

FIG. 3 is a three-dimensional schematic diagram of step 1 of embodiment 2 of the present invention.

FIG. 4 is a schematic top view of step 1 of embodiment 2 of the present invention.

FIG. 5 is a schematic diagram of step 2 of embodiment 2 of the present invention.

FIG. 6 is a schematic diagram of step 3 of embodiment 2 of the present invention.

FIG. 7 is a schematic diagram of step 4 of embodiment 2 of the present invention.

FIG. 8 is a schematic diagram of step 5 of embodiment 2 of the present invention.

FIG. 9 is a schematic diagram of step 6 of embodiment 2 of the present invention.

FIG. 10 is a schematic diagram of step 7 of embodiment 3 of the present invention.

FIG. 11 is a schematic diagram of step 8 of embodiment 3 of the present invention.

FIG. 12 shows the range of two adjacent cylindrical holes in the fourth embodiment.

FIG. 13 shows the position of the isolation hole in the fourth embodiment.

FIG. 14 shows a schematic diagram of step 2 of embodiment 4.

FIG. 15 shows a schematic diagram of step 3 of embodiment 4.

FIG. 16 shows a schematic diagram of step 4 of embodiment 4.

FIG. 17 shows a schematic diagram of step 5 of embodiment 4.

FIG. 18 shows a schematic diagram of step 6 of embodiment 4.

FIG. 19 shows a schematic diagram of step 7 of embodiment 4.

FIG. 20 shows a schematic diagram of Embodiment 5.

### DETAILED DESCRIPTION OF THE INVENTION

The fabricating method of three-dimensional programmable memory includes the following steps:

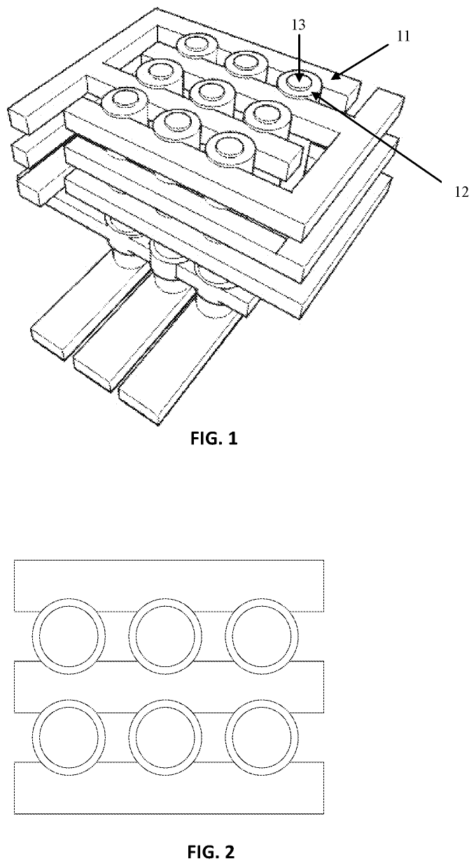

FIG. 1 shows one of the semiconductor memory structures fabricated by the present invention. Here, 11 is a conductive medium, 12 is a first dielectric layer, and 13 is a core dielectric layer. In FIG. 2, the area shown by the elliptical line indicates the memory body.

Embodiment 1: This embodiment is a two-layer cylindrical structure, see FIG. 1 and FIG. 2. The materials of the conductive medium layer, the first medium layer and the core medium layer can be any one of the combinations in Table 1.

TABLE 1

| | Conductive | First | Core |
|---|---|---|---|
| | medium layer | medium layer | medium layer |
| Combination 1 | P-type | Insulating | N-type |
| | semiconductors | dielectrics | semiconductors |
| Combination 2 | N-type | Insulating | P-type |
| | semiconductors | dielectrics | semiconductors |
| Combination 3 | Schottky | Insulating | semiconductors |
| | metals | dielectrics | |
| Combination 4 | semiconductors | Insulating | Schottky |
| | | dielectrics | metals |
| Combination 5 | conductors | retentive | conductors |
| | | medium | |

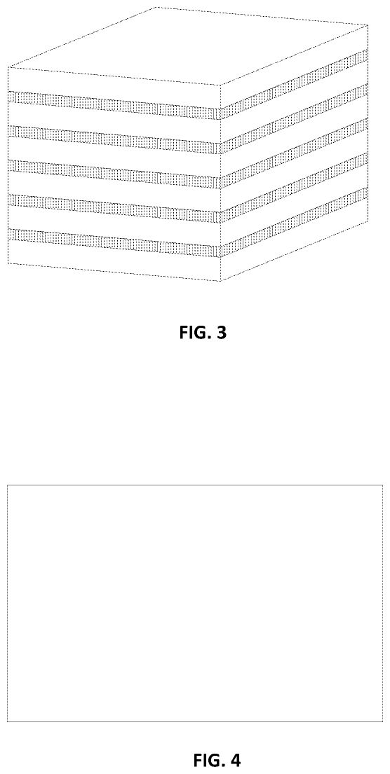

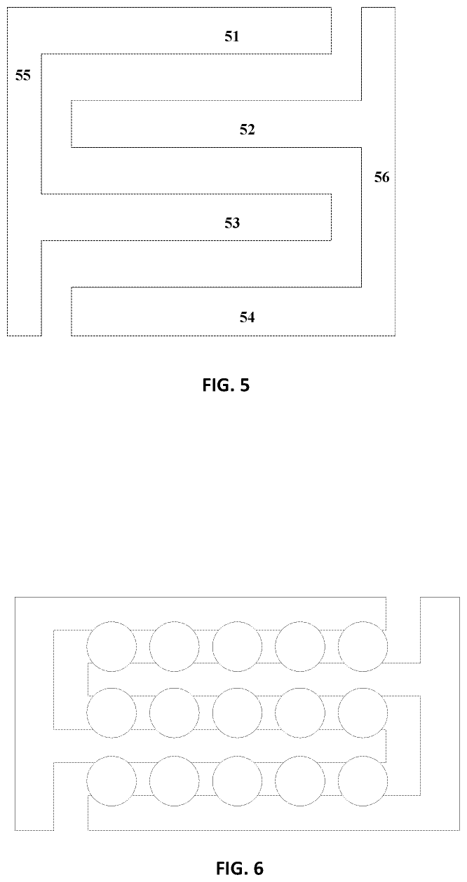

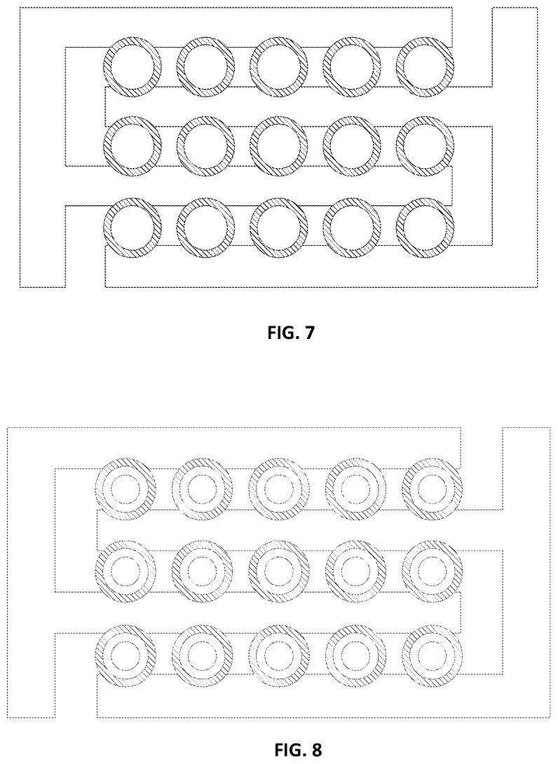

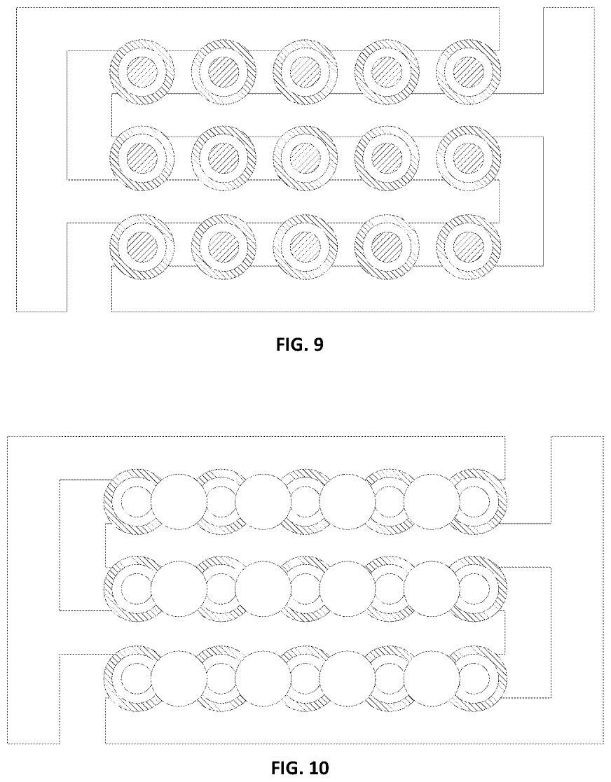

Embodiment 2: The cylindrical structure in this embodiment has a three-layer structure.
Step 1: Using a deposition process to set a predetermined number of conductive medium layers and insulating medium layers in a manner that the conductive medium layer and the insulating medium layer are vertically stacked one onto another to form the base structure body. FIG. 3 is a three-dimensional schematic diagram of the basic structure, and FIG. 4 shows a top view.
Step 2: Using the mask definition and deep trench etching process, an isolation trench 50 from the top layer to the bottom layer of the basic structure to form two interdigitated structures, which includes at least two fingers and one commonly connecting strip, and each finger strip is connected to the commonly connecting strip in the interdigital structure, and the isolation trench is filled with an insulating medium. In FIG. 5, 51, 52, 53, 54 are finger strips, and 55, 56 are commonly connecting strips. The fingers 51, 53 and the commonly connecting strip 55 form the first interdigital structure, and the fingers 52, 54 are connected to the common strip 56, which forms the second interdigital structure. The fingers of the two interdigital structures are set staggered, as shown in FIG. 5.
Step 3: Using the mask definition and deep trench etching process, trench holes 60 from the top layer to the bottom layer of the base structure at the isolation trench are set to form an array of trench holes; The area between the fingers is called the inter-finger area, and the cylindrical trench holes in the same inter-finger area are the ones in the same row, as shown in FIG. 6.
Step 4: Using the ALD process to grow a layer of programmable medium with a thickness of 0.5-5 nm on the inner wall of the cylindrical hole as the first medium layer, as shown in FIG. 7;
Step 5: Using the ALD process to grow a layer of buffer layer on the inner wall of the cylindrical hole (that is, the surface of the first medium layer) as the second dielectric layer, the thickness of which is optimized according to the requirements of programming the leakage current of the reverse diode, as shown in FIG. 8.
Step 6: The ALD process is used to deposit and fill the core medium material in the cavity left by previous steps inside the cylindrical hole to form the core medium material layer. The core medium material can be conducting semiconductor or Schottky metal, as shown in FIG. 9.

The materials of the conductive medium layer, the first and second medium layer and the core medium layer can be preselected in any one of the combinations in Table 2.

TABLE 2

| | Conductive | First | Second | Core |
|---|---|---|---|---|
| | medium layer | medium layer | medium layer | medium layer |
| Combination 11 | P+ type | Insulating | Lightly-doped | N+ type |
| | semiconductors | dielectrics | N-type | semiconductors |
| | | | semiconductors | or conductors |
| Combination 12 | N+ type | Lightly -doped | Insulating | P+ type |
| | semiconductors | N-type | dielectrics | semiconductors |
| | or conductors | semiconductors | | |
| Combination 13 | P-type Schottky | Insulating | Lightly -doped | N+ type |
| | metals | dielectrics | N-type | semiconductors |
| | | | semiconductors | or conductors |
| Combination 14 | N-type Schottky | Insulating | Lightly-doped | P+ type |
| | metals | dielectrics | P-type | semiconductors |
| | | | semiconductors | or conductors |

Embodiment 3: This embodiment has the following steps after Step 6 of Embodiment 2:

Step 7: Using the mask definition and deep trench etching process to set isolation trench holes between the center points of two adjacent cylindrical trench holes in the same array, and the isolation hole encroaches the two adjacent cylindrical holes, and the edge of the isolation hole locates in the middle of the center points of the two adjacent cylindrical holes, that is to say, after the isolation hole is trenched, the core medium layer in the cylindrical holes remains as a whole, as shown in FIG. 10.

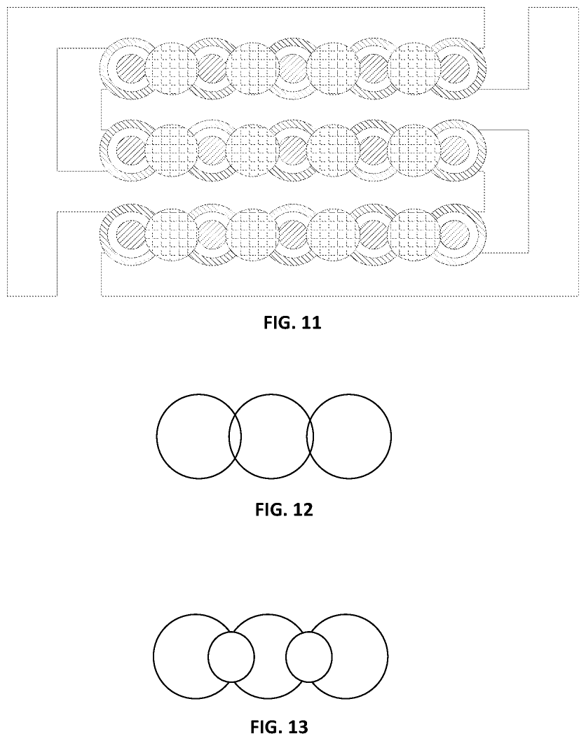

Step 8: Using the ALD method to fill the isolation trench holes with insulating materials, as shown in FIG. 11.

The cylindrical holes in Embodiment 2 and Embodiment 3 are independent of each other. In Embodiment 4, adjacent cylindrical trench holes in the same array can encroach upon each other. Since the isolation hole will be set in the subsequent process, it will completely isolate the relevant memory media in the two adjacent cylindrical holes. The nearest edge of the encroaching party is between the center point of the invading party and the center point of the encroached party. Here the nearest edge refers to the edge closest to the center point of the encroaching party to maintain the integrity of the core medium, refer to FIG. 12 and FIG. 13. FIG. 12 shows the range of two adjacent cylindrical trench holes, and FIG. 13 shows the location of the isolation trench holes.

Embodiment 4: This is an improved embodiment. It specifically includes the following steps:

1: Forming a base structure body: a predetermined number of conductive medium layers and insulating medium layers are set in a manner that the conductive medium layer and the insulating medium layer are vertically stacked one onto another to form the base structure body; this step is the same as the second embodiment.

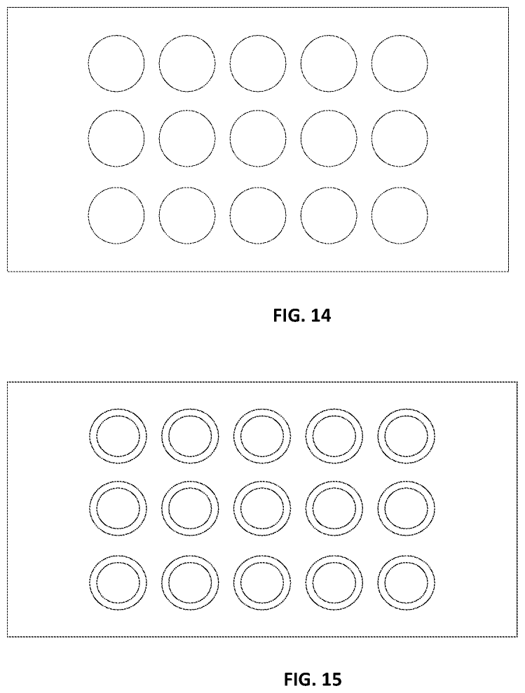

2: Using the mask definition and deep trench etching process to set an array of trench holes at the isolation trench to form cylindrical trench holes penetrating from top layer to the bottom layer of the base structure; the area between two adjacent arrays of cylindrical trench holes is in the finger strip region, shown in FIG. 14.

3. Using the ALD process to grow a 0.5-5nm programmable dielectric on the inner wall surface of the cylindrical hole to form the first dielectric layer, as shown in FIG. 15.

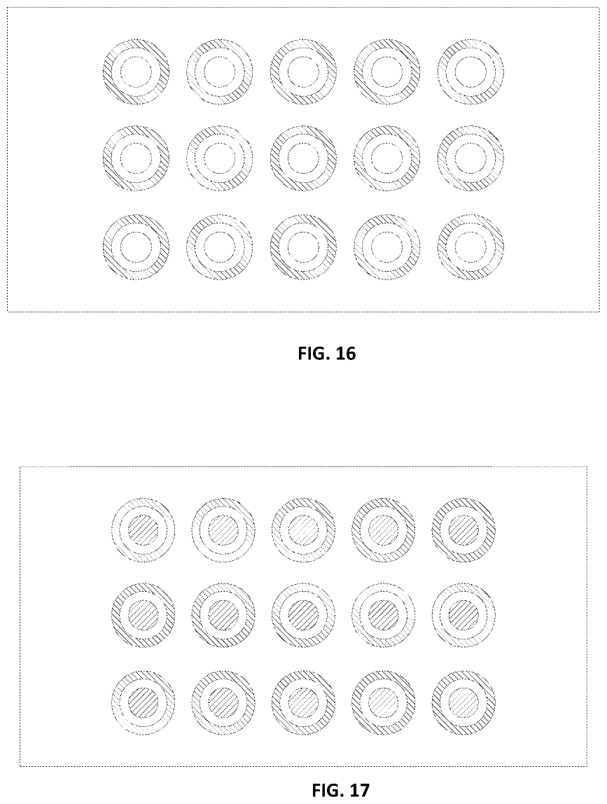

4. Using the ALD process to grow a layer of buffer layer on the inner wall of the cylindrical hole (that is, the surface of the first medium layer) as the second dielectric layer, the thickness of which is optimized according to the requirements of programming the leakage current of the reverse diode, shown in FIG. 16.

5. The ALD process is used to deposit and fill the core medium material in the cavity left by previous steps inside the cylindrical hole to form the core medium material layer. The core medium material can be conducting semiconductor or Schottky metal, as shown in FIG. 17;

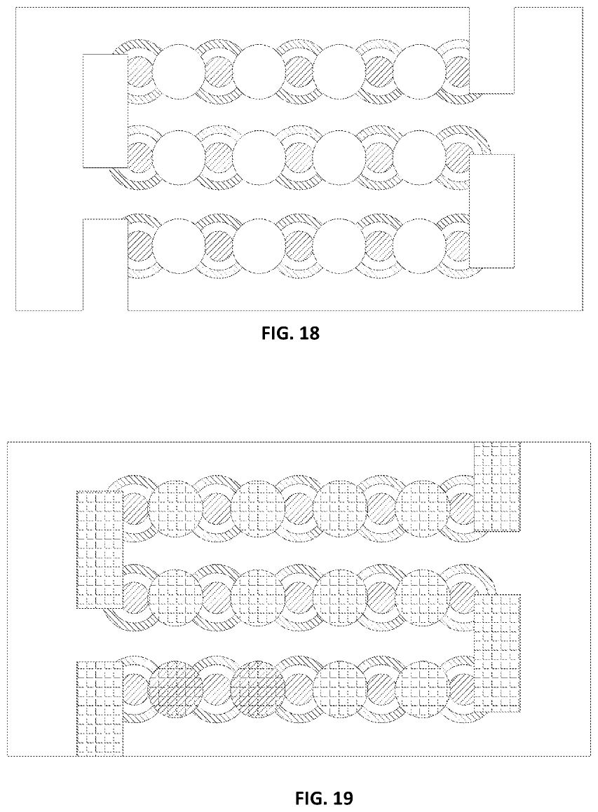

6. Isolation trench holes are set between two adjacent cylindrical holes in the same row, and isolation trenches are set at the two ends of each array of cylindrical trench holes. The isolation trench holes encroach the core medium material in the cylindrical trench holes. The isolation trenches are alternately set at the two ends of each finger area, to form two staggered interdigitated structures, as shown in FIG. 18.

7. Filling the isolation trench and the isolation trench hole with an insulating medium, as shown in FIG. 19.

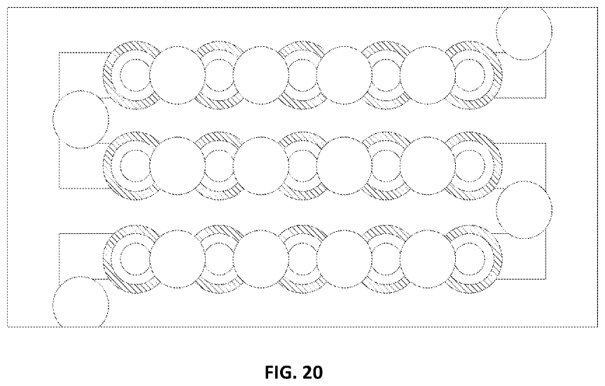

Embodiment 5: The interdigital structure of this embodiment is finally formed by trenching holes at the ends of the finger strips, refer to FIG. 20, which is different from

Embodiments 2 and 3, where a complete interdigital structure with isolation trenches is form first. The hole at the end of the finger strip can be either a cylindrical trench hole as a memory unit, or an isolation trench hole. The former is equivalent to increasing the number of memory units.

What is claimed is:

1. A fabrication method of a three-dimensional programmable memory, characterized in that it comprises the following steps:

1. Form a basic structure: set a predetermined number of conductive medium layers and insulating medium layers in a way that the conductive medium layer and the insulating medium layer are vertically stacked one onto another to form the base structure body;

2. Form the interdigital structure on the basic structure body: the basic structure body is divided into two interdigitated interdigital structures by setting a segmenting structure that trenches from the top layer to the bottom layer of the basic structure body, and the interdigital structure includes at least two fingers and one commonly connecting strip, each finger strip in the same interdigitated structure is connected with the commonly connecting strip; the segmenting structure includes an array of cylindrical trench holes and an isolation trench filled with insulating material; The area between the fingers is called the inter-finger area, and the cylindrical trench holes in the same inter-finger area are the ones in the same row.

3. Forming the cylindrical memory unit: according to the preset memory structure, the required intermediate medium layer materials are set layer by layer onto the inner wall of the cylindrical trench hole, and finally the core medium material is filled in the cylindrical trench hole to form the core medium material layer.

2. The fabrication method for preparing a programmable memory according to claim 1, where the preset memory structure in the step in 3) is one of the following structures:
PN junction semiconductor memory structure, Schottky semiconductor memory structure, and retentive medium memory structure; the retentive medium memory is the resistance change memory, magnetic phase change memory, phase change memory, ferroelectric memory.

3. The fabrication method for preparing a programmable memory according to claim 1, where in the step 2), the cylindrical trench holes are separated from one another.

4. The fabrication method for preparing a programmable memory according to claim 1, where the step 2) includes the following steps:
2a. Divide the basic structure into two staggered interdigitated structures by setting an isolation trench from the top layer to the bottom of the basic structure. The interdigitated structure includes at least two fingers and a commonly connecting strip, and each finger in the interdigitated structure is connected to the commonly connecting strip in the same interdigitated structure;
2b. Fill the isolation trench with insulating material;
2c. Drill trench holes at the isolation trench to form cylindrical trench holes penetrating from top layer to the bottom layer of the base structure, and the cylindrical trench hole encroaches the conductive medium layers and the insulating medium layers of the interdigital structure.

5. The fabrication method for preparing a programmable memory according to claim 1, where the step 2) includes the following step:
The isolation trench hole is set between the center points of two adjacent cylindrical holes in the same row, and encroaches the two adjacent cylindrical trench holes, and the edge of the isolation trench hole is located between the center points of the two adjacent cylindrical holes; Fill the isolation trench hole with insulating material.

6. The fabrication method for preparing a programmable memory according to claim 4, where in the step 2), in the cylindrical trench hole array, the adjacent holes in the same row can encroach upon each other. The “nearest” edge of the encroaching hole is between the center point of the encroaching hole and the center point of the encroached hole. Here the “nearest” edge is the edge closest to the center of the invaded hole.

7. The fabrication method for preparing a programmable memory according to claim 1, where the sequence of the steps is:
A) Forming a base structure body: a predetermined number of conductive medium layers and insulating medium layers are set in a manner that the conductive medium layer and the insulating medium layer are vertically stacked one onto another to form the base structure body;
B) Forming the interdigital structure on the basic structure:
B1. Divide the basic structure into two staggered interdigitated structures by setting an isolation trench from the top layer to the bottom of the basic structure. The interdigitated structure includes at least two fingers and a commonly connecting strip, and each finger in the interdigitated structure is connected to the commonly connecting strip in the same interdigitated structure;
B2. Fill the isolation trench with insulating material;
B3. Drill an array of trench holes at the isolation trench to form cylindrical trench holes penetrating from top layer to the bottom layer of the base structure, and the area between the fingers is called the inter-finger area, and the cylindrical trench holes in the same inter-finger area are the ones in the same row.
C) Forming a cylindrical memory unit: according to the preset memory structure, the required intermediate medium layer materials are set layer by layer onto the inner wall of the cylindrical trench hole, and finally the core medium material is filled in the cylindrical trench hole to form the core medium material layer.

8. The fabrication method for preparing a programmable memory according to claim 1, where the sequence of the steps is:
I) Forming a base structure body: a predetermined number of conductive medium layers and insulating medium layers are set in a manner that the conductive medium layer and the insulating medium layer are vertically stacked one onto another to form the base structure body;
II) Forming the prototype of the interdigital structure and the cylindrical trench unit on the basic structure:
Il 1. Drill an array of trench holes at the isolation trench to form cylindrical trench holes penetrating from top layer to the bottom layer of the base structure; the area between two adjacent arrays of cylindrical trench holes is in the finger strip region;
II 2. According to the preset memory structure, the required intermediate medium layer materials are set layer by layer onto the inner wall of the cylindrical trench hole, and finally the core medium material is filled in the cylindrical trench hole to form the core medium material layer;
III) Forming the prototype of the interdigital structure: isolation trench holes are set between two adjacent cylindrical holes in the same row, and isolation trenches are set at the two ends of each array of cylindrical trench holes. The isolation trench holes encroach the core medium material in the cylindrical trench holes. The isolation trenches are alternately set at the two ends of each finger area, to form two staggered interdigitated structures. And the isolation trenches and isolation trench holes are filled with insulating medium.

9. The fabrication method for preparing a programmable memory according to claim 1, where the insulating medium in the isolation trench and the isolation trench hole can be silicon dioxide or air.

10. The fabrication method for preparing a programmable memory according to claims 1, 2, 3, 4, 5, 6, 7, 8, and 9, where the materials of the conductive medium layer, the first medium layer and the core medium layer can be any one of the combinations in the following table:

| | Conductive | First | Core |
|---|---|---|---|
| | medium layer | medium layer | medium layer |
| Combination 1 | P-type | Insulating | N-type |
| | semiconductors | dielectrics | semiconductors |
| Combination 2 | N-type | Insulating | P-type |
| | semiconductors | dielectrics | semiconductors |
| Combination 3 | Schottky | Insulating | semiconductors |
| | metals | dielectrics | |
| Combination 4 | semiconductors | Insulating | Schottky |
| | | dielectrics | metals |
| Combination 5 | conductors | retentive | conductors |
| | | medium | |

11. The fabrication method for preparing a programmable memory according to claims 1, 2, 3, 4, 5, 6, 7, 8, and 9, where the materials of the conductive medium layer, the first and second medium layer and the core medium layer can be any one of the combinations in the following table:

| | Conductive | First | Second | Core |
|---|---|---|---|---|
| | medium layer | medium layer | medium layer | medium layer |
| Combination 11 | P+ type | Insulating | Lightly-doped | N+ type |
| | semiconductors | dielectrics | N-type | semiconductors |
| | | | semiconductors | or conductors |
| Combination 12 | N+ type | Lightly -doped | Insulating | P+ type |
| | semiconductors | N-type | dielectrics | semiconductors |
| | or conductors | semiconductors | | |
| Combination 13 | P-type Schottky | Insulating | Lightly -doped | N+ type |
| | metals | dielectrics | N-type | semiconductors |
| | | | semiconductors | or conductors |
| Combination 14 | N-type Schottky | Insulating | Lightly-doped | P+ type |
| | metals | dielectrics | P-type | semiconductors |
| | | | semiconductors | or conductors |
